(19) United States
(12) Patent Application Publication
(10) Pub. No.: US 2025/0224607 A1
(43) Pub. Date: Jul. 10, 2025

(54) ELECTROMAGNETIC WAVE DEFLECTION DEVICE AND ELECTROMAGNETIC WAVE SCANNING DEVICE

(71) Applicant: KYOCERA Corporation, Kyoto (JP)

(72) Inventor: Hiroki OKADA, Machida-shi, Tokyo (JP)

(73) Assignee: KYOCERA Corporation, Kyoto (JP)

(21) Appl. No.: 18/845,248

(22) PCT Filed: Mar. 23, 2023
(86) PCT No.: PCT/JP2023/011601

§ 371 Date: Sep. 9, 2024

(30) Foreign Application Priority Data
Mar. 29, 2022 (JP) 2022-054373

(51) Int. Cl. G02B 26/08; G02B 7/182; G02B 26/10

(52) U.S. Cl. CPC G02B 26/0833; G02B 7/1821; G02B 26/101

(57) ABSTRACT

An electromagnetic wave deflection device includes: a mirror configured to reflect electromagnetic waves; a first drive unit; a second drive unit; and a weight. The first drive unit tilts the mirror with a first axis as a tilt axis. The second drive unit tilts the mirror with a second axis intersecting the first axis as a tilt axis. The weight is located in at least one of the first drive unit or the second drive unit in a manner in which a resonance frequency of the second drive unit differs from natural number multiples of a resonance frequency of the first drive unit.

### CROSS-REFERENCE TO RELATED APPLICATIONS

The present application claims priority from Japanese Patent Application No. 2022-54373 (filed Mar. 29, 2022), the disclosure of which is hereby incorporated by reference herein in its entirety.

### TECHNICAL FIELD

The present disclosure relates to an electromagnetic wave deflection device and an electromagnetic wave scanning device.

### BACKGROUND OF INVENTION

In a known optical deflector, the positional deviation of the pivot axis of a mirror when turning is reduced (for example, refers to Patent Literature 1).

### CITATION LIST

### Patent Literature

Patent Literature 1: Japanese Unexamined Patent Application Publication No. 2016-9050

### SUMMARY

In an embodiment of the present disclosure, an electromagnetic wave deflection device includes: a mirror configured to reflect electromagnetic waves; a first drive unit; a second drive unit; and a weight. The first drive unit tilts the mirror with a first axis as a tilt axis. The second drive unit tilts the mirror with a second axis intersecting the first axis as a tilt axis. The weight is located in at least one of the first drive unit or the second drive unit in a manner in which a resonance frequency of the second drive unit differs from natural number multiples of a resonance frequency of the first drive unit.

In an embodiment of the present disclosure, an electromagnetic wave scanning device includes: the electromagnetic wave deflection device; and an emission device configured to emit electromagnetic waves into the electromagnetic wave deflection device.

### BRIEF DESCRIPTION OF THE DRAWINGS

FIG. 1 is a plan view of a configuration example of an electromagnetic wave deflection device according to an embodiment of the present disclosure.

FIG. 2 is a plan view of a configuration example of an electromagnetic wave deflection device including a mirror overlapping second drive units.

FIG. 3 is a cross-sectional view taken along line A-A in FIG. 2.

FIG. 4 is a plan view of a configuration example of an electromagnetic wave deflection device including a weight surrounding an opening of a first drive unit.

FIG. 5 is a plan view of a configuration example of an electromagnetic wave deflection device including second drive units each including multiple turning portions.

### DESCRIPTION OF EMBODIMENTS

### (Configuration Examples of Electromagnetic Wave Deflection Device 1)

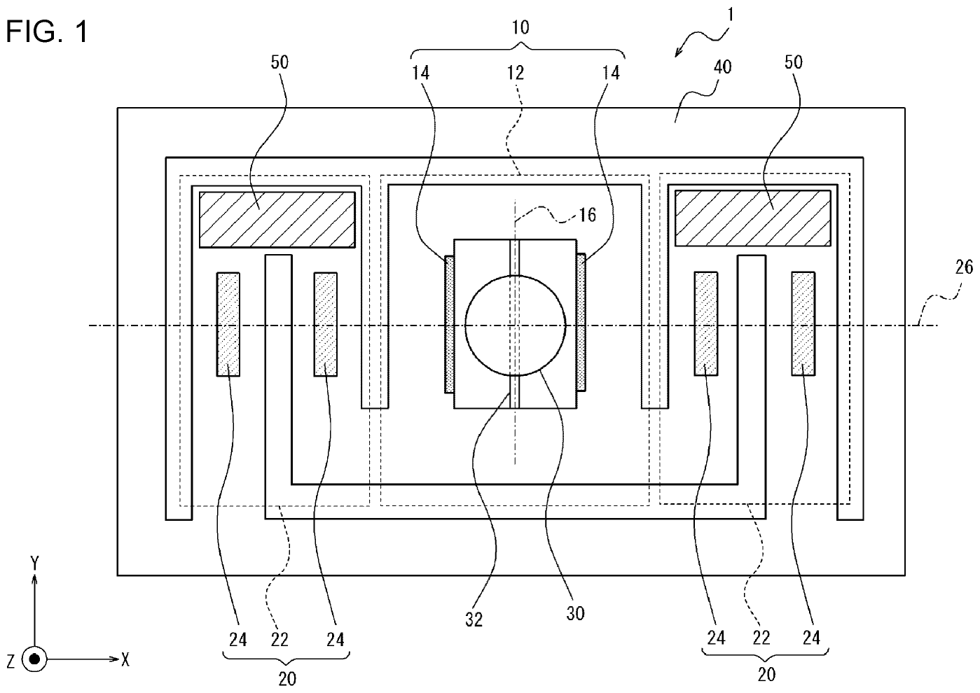

As illustrated in FIG. 1, an electromagnetic wave deflection device 1 according to an embodiment includes a substrate 40 and a mirror 30. The mirror 30 includes a reflection surface that reflects incident electromagnetic waves. The substrate 40 includes a first drive unit 10 and second drive units 20. The first drive unit 10 includes a first support portion 12 and first actuators 14. Each second drive unit 20 includes a second support portion 22 and second actuators 24. The first support portion 12 is located between the two second support portions 22 aligned in the X-axis direction. The second support portions 22 are portions supporting the first support portion 12. The substrate 40 includes an outer frame portion in a frame shape, and the second support portions 22 are connected to this outer frame portion. In other words, the substrate 40 includes the outer frame, the first support portion 12, and the second support portions 22. The outer frame portion, the first support portion 12, and the second support portions 22 of the substrate 40 may be formed by a manufacturing process based on a technology of the micro electro mechanical systems (MEMS). Note that the X-axis direction corresponds to one of the surface directions of the substrate 40. The Y-axis direction is orthogonal to the X-axis direction. The Z-axis direction corresponds to the direction perpendicular to the surface of the substrate 40.

The first support portion 12 is a portion supporting the mirror 30 and a mirror support portion 32 supporting the mirror 30. The first support portion 12 has, for example, a quadrangular shape and has an opening in the quadrangular shape. In other words, the first support portion 12 has a frame shape. The mirror support portion 32 is a beam extending in the Y-axis direction in the opening in the first support portion 12. The opening in the first support portion 12 may be quadrangular. The mirror support portion 32 has a shape of an elongated beam, the ends of which are connected to one side and the side facing the one side of the opening in the first support portion 12. The mirror 30 is located above the mirror support portion 32 with a pillar member 32A interposed in between and is capable of tilting with the mirror support portion 32 as the axis. The mirror 30 may be formed above the substrate 40 by a manufacturing process based on the MEMS technology. The mirror support portion 32 may be formed on the substrate 40 or may be formed integrally with the substrate 40 by a manufacturing process based on the MEMS technology. The mirror 30 may be supported by sides forming the opening of the first support portion 12 with two mirror support portions 32 interposed in between, without the interposition of the pillar member 32A. When the mirror 30 tilts with the mirror support portion 32 as the axis, the axis is illustrated as a first axis 16 extending in the Y-axis direction.

The first actuators 14 are located in the first support portion 12. The first actuators 14 may be located on both sides of the longitudinal axis of the mirror support portion 32. The first actuators 14 may be located symmetrical with respect to the longitudinal axis of the mirror support portion 32. The first actuators 14 may be located along edges of the opening in the first support portion 12. The first actuators 14 are capable of expanding and contracting in the Y-axis direction. The first actuators 14 may be, for example, piezoelectric elements, motors, or the like. Expansion and contraction of the first actuators 14 in the Y-axis direction generate vibration at side portions forming the opening of the first support portion 12. The vibration at the edges of the opening of the first support portion 12 is transmitted through the mirror support portion 32 to the mirror 30. The vibration transmitted to the mirror 30 causes the mirror 30 on the mirror support portion 32 to resonate in the direction in which the mirror 30 tilts with the first axis 16 as the axis. When the mirror 30 resonates in the tilting direction around the first axis 16, the mirror 30 sways around the first axis 16. If electromagnetic waves are incident on the mirror 30 from the positive direction of the Z-axis, the electromagnetic waves are reflected on the mirror 30 swaying around the first axis 16 and scan in the X-axis direction.

The second support portion 22 may have a so-called meander shape (turning shape). In the case in which the second support portion 22 has a meander shape, the second support portion 22 includes portions extending in the Y-axis direction and a turning portion. The turning portion extends in the X-axis direction and connects the portions extending in the Y-axis direction. The portions extending in the Y-axis direction may be longer than the turning portion. The second support portions 22 connect the first support portion 12 to the outer frame portion of the substrate 40. In the case in which the first support portion 12 has a quadrangular shape having the sides extending in the X-axis direction and the Y-axis direction, each second support portion 22 connects one end of a side extending in the Y-axis direction of the first support portion 12 to the substrate 40. Note that the second support portion 22 is not limited to one having a meander shape. The second actuators 24 are located in the portions of the second support portion 22 extending in the Y-axis direction. The second actuator 24 has a shape elongated in the Y-axis direction. The second actuator 24 is capable of expanding and contracting in the Y-axis direction. The second actuators 24 may be, for example, piezoelectric elements, motors, or the like. When the second actuators 24 expand and contract in the Y-axis direction, the portions of the second support portions 22 extending in the Y-axis direction tilt around an axis parallel to the X-axis direction. The tilt axis of the second support portions 22 is illustrated as a second axis 26. The second axis 26 is assumed to be an axis intersecting the first axis 16. When the portions of the second support portions 22 extending in the Y-axis direction tilt around the second axis 26, the first support portion 12 tilts around the second axis 26. When the first support portion 12 tilts around the second axis 26, the mirror 30 supported by the mirror support portion 32 located in the opening in the first support portion 12 tilts around the second axis 26. The tilt angle of the mirror 30 around the second axis 26 is controlled according to the degree of the expansion and contraction of the second actuators 24. If electromagnetic waves are incident on the mirror 30 from the positive direction of the Z-axis, the electromagnetic waves reflected on the mirror 30, the tilt angle of which around the second axis 26 is controlled, scan in the Y-axis direction.

When the mirror 30 resonates at a natural resonance frequency of the first drive unit 10, the mirror 30 sways around the first axis 16. Regardless of the resonance of the first drive unit 10, expansion and contraction of the second actuators 24 deform the second drive units 20, which tilts the first drive unit 10 around the second axis 26, and thereby, the mirror 30 tilts around the second axis 26. The tilt angle of the mirror 30 around the second axis 26 can be controlled by the degree of the expansion and contraction of the second actuators 24.

The second drive units 20 are configured to tilt around the second axis 26 in order that the first drive unit 10 and the mirror 30 supported by the second drive units 20 can be tilted around the second axis 26. In this case, when the second drive units 20 resonate due to external vibration transmission, the second drive units 20 sway so as to tilt around the second axis 26. If the resonance frequency of the second drive units 20 coincides with the resonance frequency of the first drive unit 10 or a natural number multiple (1×, 2×, 3×, and so on) of the resonance frequency of the first drive unit 10, the second drive units 20 are likely to resonate due to vibration at the resonance frequency of the first drive unit 10, transmitted from the first drive unit 10 to the second drive units 20. When the second drive units 20 resonate, the second drive units 20 sway around the second axis 26. When the second drive units 20 resonate, the electromagnetic wave deflection device 1 cannot control the tilt angle of the second drive units 20 around the second axis 26 by using the degree of the expansion and contraction of the second actuators 24.

Conversely, in the case in which the resonance frequency of the second drive units 20 differs from the natural number multiples (1×, 2×, 3×, and so on) of the resonance frequency of the first drive unit 10, even if vibration at the resonance frequency of the first drive unit 10 reaches the second drive units 20, the second drive units 20 are less likely to resonate. For example, in the case in which the resonance frequency of the second drive units 20 is half of an odd multiple of the resonance frequency of the first drive unit 10 (1.5×, 2.5×, 3.5×, and so on), even if vibration at the resonance frequency of the first drive unit 10 reaches the second drive units 20, the second drive units 20 hardly resonate.

Hence, the electromagnetic wave deflection device 1 according to the present embodiment is configured such that the resonance frequency of the second drive units 20 differs from the natural number multiples of the resonance frequency of the first drive unit 10 so that the second drive units 20 are less likely to resonate due to the vibration of the first drive unit 10. In this case, the second drive units 20 and the first drive unit 10 and mirror 30 supported by the second drive units 20 are less likely to resonate around the second axis 26. In other words, when the mirror 30 resonates around the primary axis (the first axis 16), the resonance around the secondary axis (the second axis 26) intersecting the primary axis can be lower.

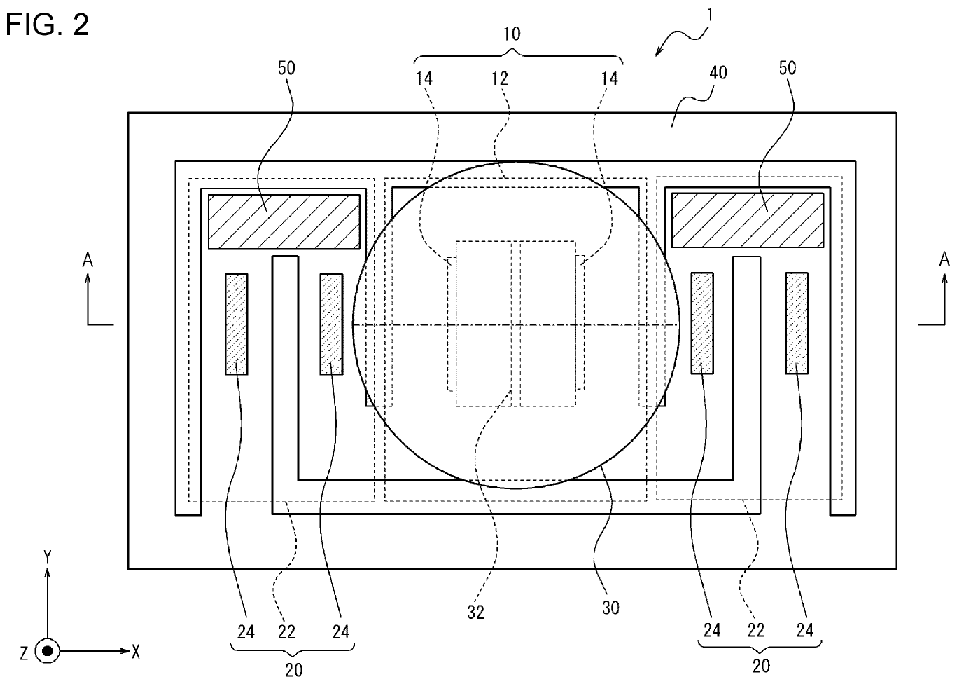

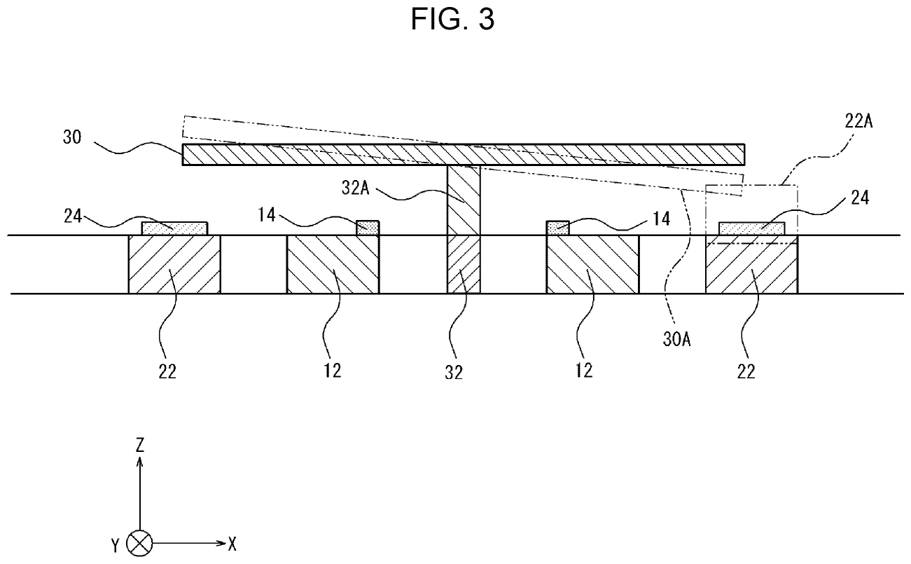

As illustrated in FIG. 2, in some configurations, the mirror 30 overlaps the second drive units 20 in plan view (view in the positive direction of the Z-axis) of the substrate 40 of the electromagnetic wave deflection device 1. As illustrated in a cross-sectional view of FIG. 3, the mirror 30 can tilt clockwise in the positive direction of the X-axis and move to the position of the mirror 30A. In addition, when the second drive units 20 resonate, a second support portion 22 can be displaced in the positive direction of the Z-axis and move to the position of the second support portion 22A. In this case, the mirror 30A can collide with the second support portion 22A. In the case in which the electromagnetic wave deflection device 1 is configured such that the second drive units 20 are less likely to resonate around the second axis 26, the mirror 30 is less likely to collide with the second support portions 22. This can improve the reliability of the electromagnetic wave deflection device 1.

In addition, the first drive unit 10 supporting the mirror 30 can be affected by the resonance of the second drive units 20 around the second axis 26. When the resonance of the second drive units 20 around the second axis 26 reaches the first drive unit 10, there is a possibility that the mirror 30 supported by the first drive unit 10 can vibrate around the second axis 26. Vibration of the mirror 30 around the second axis 26 makes control of the tilt angle of the mirror 30 around the second axis 26 difficult. In the case in which the electromagnetic wave deflection device 1 is configured such that the second drive units 20 are less likely to resonate around the second axis 26, control of the tilt angle of the mirror 30 around the second axis 26 is easier in the electromagnetic wave deflection device 1. This can improve the reliability of the electromagnetic wave deflection device 1.

The resonance frequency of the second drive units 20 is determined by the elastic modulus of the second support portion 22 and the moment of inertia around the second axis 26. The lower the elastic modulus of the second support portion 22, the lower the resonance frequency. Hence, the elastic modulus of the second support portion 22 may be adjusted to adjust the resonance frequency of the second drive units 20. The elastic modulus of the second support portion 22 may be adjusted by the material of the second support portion 22 or the shape of the second support portion 22.

The larger the moment of inertia of the second support portion 22 around the second axis 26, the lower the resonance frequency. The moment of inertia of the second support portion 22 around the second axis 26 may be adjusted to adjust the resonance frequency of the second drive units 20. The moment of inertia of the second support portion 22 around the second axis 26 is determined by the sum total of the product of the distance from the second axis 26 to each portion of the second support portion 22 multiplied by the mass of each portion. As illustrated in FIG. 1, the electromagnetic wave deflection device 1 according to the present embodiment includes weights 50 at the turning portions away from the second axis 26 of the second support portions 22 in order to adjust the resonance frequency of the second drive units 20. The larger the mass of the weight 50 is, or the farther from the second axis 26 the position of the weight 50 is, the lower the resonance frequency of the second drive units 20.

When the weights 50 are located in the second drive units 20, the weights 50 may be located so as not to overlap the second actuators 24 in plan view of the substrate 40. This makes it easy for the output of the second actuators 24 to tilt the first drive unit 10 and the mirror 30. Thus, the energy efficiency for tilting the mirror 30 around the second axis 26 is less likely to decrease by the weights 50.

The electromagnetic wave deflection device 1 may have a configuration in which the resonance frequency of the second drive units 20 is lower than the resonance frequency of the first drive unit 10. In this case, the resonance frequency of the second drive units 20 has a value away from any of the natural number multiples of the resonance frequency of the first drive unit 10. This makes the second drive units 20 less likely to resonate. Specifically, when the resonance is caused to occur around the primary axis, the resonance around the secondary axis intersecting the primary axis can be lower.

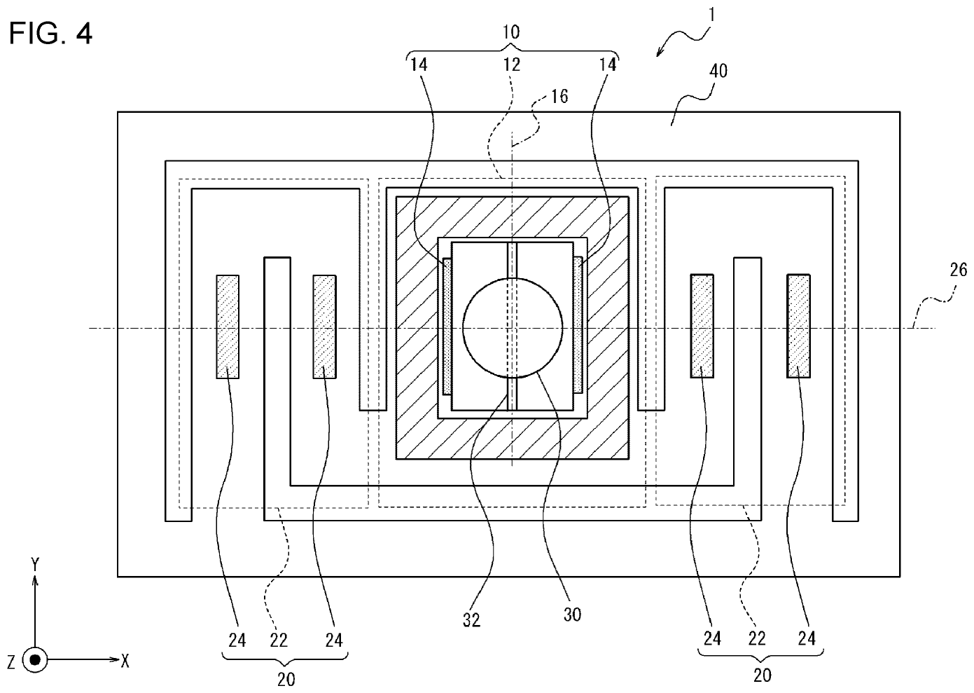

As illustrated in FIG. 4, a weight 50 may be located in the first drive unit 10. In the example in FIG. 4, a weight 50 surrounds the opening of the first support portion 12. The weight 50 is not limited to one having such a position and may be located at at least a portion of the first support portion 12. A weight 50 may be located, for example, along at least one side of the opening of the first support portion 12. A weight 50 may be located along a side parallel to the first axis 16, of the edges of the opening of the first support portion 12 or may be located along a side intersecting the first axis 16. A weight 50 may be located along each of two sides of the opening facing each other. A weight 50 may be located along each of the two right and left sides of the opening (the sides parallel to the first axis 16) or may be located along each of the two upper and lower sides of the opening (the sides intersecting the first axis 16).

In the case in which a weight 50 is located in the first drive unit 10, the weight 50 may be located so as not to overlap the first actuators 14 in plan view of the substrate 40. A weight 50 may be located farther away from the mirror support portion 32 than the first actuators 14. This makes it easy for the output of the first actuators 14 to reach the mirror 30. Hence, the energy efficiency for vibrating the mirror 30 is less likely to decrease due to the weight 50.

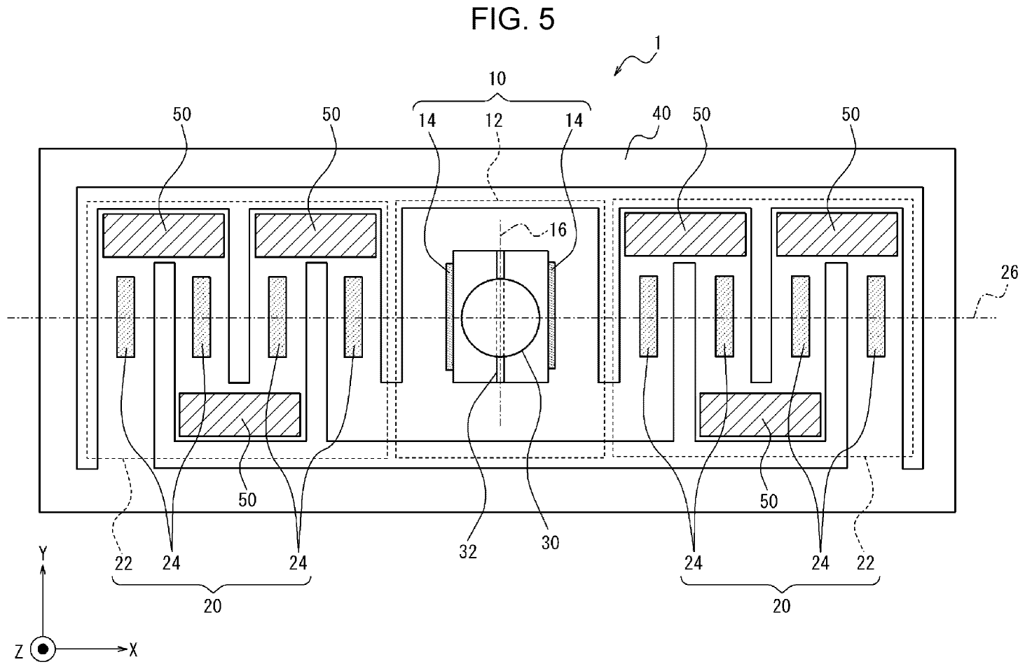

As illustrated in FIG. 5, in the case in which the second drive unit 20 includes multiple turning portions, a weight 50 may be located in each turning portion. A weight 50 may be located in only some of the turning portions, not all of the turning portions. A weight 50 may be located in only turning portions close to the first drive unit 10. A weight 50 may be located in only the turning portions of the second drive unit 20 connected to portions that overlap the mirror 30 in plan view of the substrate 40. A weight 50 may be located such that the resonance frequency, around the second axis 26, of the portion of the second drive unit 20 connected to the first drive unit 10 differs from the resonance frequency of the first drive unit 10.

In the substrate 40, the first drive unit 10 or the second drive units 20 can vibrate in various vibration modes. The vibration modes may include a first mode (secondary-axis scanning), a second mode (another mode of secondary-axis scanning), a third mode (meanders anti-phase vibration), a fourth mode (meanders in-phase vibration), a fifth mode (primary-axis scanning), and a sixth mode (another mode of primary-axis scanning). In the first mode, the second support portions 22 vibrate around the X-axis with the portions connected to the outer frame of the substrate 40 as pivots. In the second mode, the second support portions 22 vibrate around the X-axis with the portions on the side opposite in the Y-axis direction to the portions connected to the outer frame of the substrate 40 as pivots. In the third mode, the portions of the second support portions 22 located on the positive side and the negative side in the X-axis direction of the first support portion 12 vibrate in the opposite directions in the Z-axis direction. In the fourth mode, the portions of the second support portions 22 located on the positive side and the negative side in the X-axis direction of the first support portion 12 vibrate in the same directions in the Z-axis direction. In the fifth mode, the first support portion 12 vibrates such that the tilt direction of the first support portion 12 when tiling around the Y-axis is the same as the tilt direction of the mirror 30. In the sixth mode, the first support portion 12 vibrates such that the tilt direction of the first support portion 12 when tiling around the Y-axis is opposite to the tilt direction of the mirror 30. The direction in which the electromagnetic wave deflection device 1 reflects electromagnetic waves is determined by the vibration of the mirror 30 in the first drive unit 10. Hence, the electromagnetic wave deflection device 1 is configured such that the mirror 30 in the first drive unit 10 vibrates in specified vibration modes. In this operation, it is required that the vibration of the second drive units 20 does not hinder the mirror 30 from vibrating in the specified vibration modes. There is a possibility that the second drive units 20 can vibrate in a mode that hinders the mirror 30 from vibrating in the specified vibration modes. Hence, the weights 50 may be located in the second drive units 20 such that the second drive units 20 will not vibrate in a mode that hinders the mirror 30 from vibrating in the specified vibration modes. In the case in which the electromagnetic wave deflection device 1 vibrates in the aforementioned first and fifth modes as the specified vibration modes, the vibration in the fourth mode can occur as a hindering mode in resonance with the vibration in the fifth mode. The weights 50 may be located in the second drive units 20 such that the vibration in the fourth mode will not occur.

The weights 50 may be formed by increasing the thickness of at least part of the first support portion 12 or the second support portions 22. The thick portions in the first support portion 12 or the second support portions 22 are heavier than the other portions. Hence, the weights 50 may be thick portions in the first support portion 12 or the second support portions 22. The weights 50 may be components separate from the substrate 40. In this case, the weights 50 may be joined to the first support portion 12 or the second support portions 22. The weights 50 may be provided on either surface of the first support portion 12 or the second support portions 22 or may be provided on both surfaces. In the case in which the mirror 30 has a size overlapping the first actuators 14 or the second actuators 24 in the Z-axis direction, if the weights 50 are provided on the back surface (in other words, the surface opposite to the side on which the mirror 30 is located), the weights 50 and the mirror 30 are less likely to interfere with one another. In other words, the mirror 30 may have a size overlapping the first actuators 14 or the second actuators 24 in the direction perpendicular to the reflection surface of the mirror 30. The weights 50 may be located on the surface of the first drive unit 10 or the second drive units 20 on the side opposite to the side on which the mirror 30 is located.

### (Electromagnetic Wave Scanning Device)

The electromagnetic wave deflection device 1 may be used in combination with an emission device that emits electromagnetic waves. In this case, electromagnetic waves from the emission device may be incident on the mirror 30 of the electromagnetic wave deflection device 1, and the electromagnetic waves may be caused to scan by the mirror 30 turning with the first axis 16 and the second axis 26 as pivot axes. A configuration in which an electromagnetic wave deflection device 1 and an emission device are combined is referred to also as an electromagnetic wave scanning device. The emission device may be a light source that emits various types of light such as visible light, infrared light, and ultraviolet light. The emission device may be configured to emit various types of electromagnetic waves such as millimeter waves and terahertz waves.

The figures used for explaining the embodiments according to the present disclosure are schematic. The ratios of dimensions or the like in the drawings are not necessarily the same as those of an actual device.

Although several drawings and examples are used to describe the embodiments according to the present disclosure, it is important to note that those skilled in the art can make various variations and changes on the basis of the present disclosure. Hence, it is important to note that those variations and changes will be included in the scope of the present disclosure. For example, the functions and the like included in each component or the like can be rearranged unless doing so causes a logical contradiction. Two or more components or the like can be combined into one, or a component can be divided. It is important to note that these are included in the scope of the present disclosure.

The terms “first”, “second”, and the like in the present disclosure are identifiers to distinguish components. As for the components distinguished by being prefixed with “first”, “second”, and the like in the present disclosure, the ordinal numbers of the components can be exchanged. For example, as for the first axis 16 and the second axis 26, “first” and “second”, which are identifiers, can be exchanged with each other. The identifiers are exchanged at the same time. Also after exchanging the identifiers, the components are distinguished. Identifiers may also be eliminated. The components without identifiers are distinguished with symbols. Only on the basis of identifiers such as “first” and “second” mentioned in the present disclosure, the order of the components cannot be interpreted, or the identifiers cannot be used as a basis for the existence of an identifier with a smaller number.

In the present disclosure, the X-axis, the Y-axis, and the Z-axis are set for convenience of explanation and may be exchanged with one another. The configurations according to the present disclosure have been described by using a Cartesian coordinate system defined by the X-axis, the Y-axis, and the Z-axis. The positional relationship between the components according to the present disclosure is not limited to an orthogonal one.

### REFERENCE SIGNS

1 electromagnetic wave deflection device
10 first drive unit (12: first support portion, 14: first actuator, 16: first axis)
20 second drive unit (22: second support portion, 24: second actuator, 26: second axis)
30 mirror (32: mirror support portion, 32A: pillar member)
40 substrate
50 weight

1. An electromagnetic wave deflection device comprising:
a mirror configured to reflect electromagnetic waves;
a first drive unit configured to tilt the mirror with a first axis as a tilt axis;
a second drive unit configured to tilt the mirror with a second axis intersecting the first axis as a tilt axis; and
a weight located in at least one of the first drive unit or the second drive unit in a manner in which a resonance frequency of the second drive unit differs from natural number multiples of a resonance frequency of the first drive unit.

2. The electromagnetic wave deflection device according to claim 1, wherein
the weight is located in at least one of the first drive unit or the second drive unit in a manner in which the resonance frequency of the second drive unit is lower than the resonance frequency of the first drive unit.

3. The electromagnetic wave deflection device according to claim 1, wherein
the first drive unit comprises:
a first support portion supporting the mirror; and
a first actuator located in the first support portion, and
the weight is located in the first support portion at a position where the weight does not overlap the first actuator.

4. The electromagnetic wave deflection device according to claim 3, wherein
the second drive unit comprises:
a second support portion supporting the first support portion; and
a second actuator located in the second support portion, and
the weight is located in the second support portion at a position where the weight does not overlap the second actuator.

5. The electromagnetic wave deflection device according to claim 4, wherein
the mirror has a size overlapping the first actuator or the second actuator in a direction perpendicular to a reflection surface of the mirror, and
the weight is located on a surface of the first drive unit or the second drive unit on a side opposite to a side on which the mirror is located.

6. The electromagnetic wave deflection device according to claim 1, wherein
the weight is located in the second drive unit in a manner in which second drive unit does not vibrate in a mode that hinders the mirror from vibrating in a specified vibration mode.

7. An electromagnetic wave scanning device comprising:
the electromagnetic wave deflection device according to claim 1; and
an emission device configured to emit electromagnetic waves into the electromagnetic wave deflection device.
